(19) United States
(12) Patent Application Publication
(10) Pub. No.: US 2025/0224381 A1
(43) Pub. Date: Jul. 10, 2025

(54) HANDHELD MEASURING APPARATUS

(71) Applicant: Aktiebolaget SKF, Göteborg (SE)

(72) Inventors: Sylvain CHAUSSAT, Mont-Pres-Chambord (FR); Vincent SAUSSET, Azay-le-Rideau (FR)

(21) Appl. No.: 19/007,791

(22) Filed: Jan. 2, 2025

(30) Foreign Application Priority Data
Jan. 9, 2024 (DE) 102024200163.5

(51) Int. Cl. G01N 29/22; G01N 29/32

(52) U.S. Cl. CPC G01N 29/226; G01N 29/326

(57) ABSTRACT

A handheld measuring apparatus (1) includes a measuring head (3), a control device, and a power supply device. The measuring head (3) includes a micro-electromechanical system (11) for capturing vibrations. The micro-electromechanical system is attached to a body (4) of the measuring head (3) by a mechanical connection and is electrically connected to the control device. The micro-electromechanical system (11) is directly secured onto a circuit board (17) itself attached to the body (4) of the measuring head (3). The measuring head includes a sensor (19) and a flexible path (20) extending between the sensor and the circuit board (17). The body (4) of the measuring head (3) includes a first surface (13) for receiving the circuit board (17) and a second surface (15) for guiding the flexible path (20). The second surface (15) includes a recess (16). A portion of the flexible path (20) is guided into the recess.

### CROSS-REFERENCE TO RELATED APPLICATION

This application claims priority to German Application No. 102024200163.5, filed Jan. 9, 2024, the entirety of which is hereby incorporated by reference.

### FIELD

The present disclosure relates to the field of measuring apparatuses, such as those used for monitoring or maintenance of rotating equipment. More particularly, the present disclosure is directed to handheld or pocket measuring apparatuses.

### BACKGROUND

Rotating equipment, such as electric or thermal motors, clutches, gearboxes, reducers, pumps, or others, may be used for example in industry. Rotating equipment can be found on machines such as machine tools, transfer machines, handling robots, rolling mills, mixers, or other.

Whatever the field of use of rotating equipment, its monitoring and maintenance are useful. Various physical characteristics, like vibrations, temperatures, loads, stresses, speeds or other, can be monitored and analysed to control the condition of the equipment.

A simple and effective way to carry out checks is using a handheld or pocket device. Its size and weight allow easy transport, easy storage, and also simple and quick use. Common measurements concern vibrations and temperatures. That is why a device may include a head with a sensor to measure vibrations, or a head with a sensor to measure temperatures, or a head with several sensors, one of which for vibrations and one of which for temperatures. In a non-limiting manner, it can be an easy to use Bluetooth enabled handheld device that connects to applications that work with both IOS and Android tablets and smart phones. Combining vibrations and temperatures sensing, overall data can be viewed on the spot in real time or pushed to the cloud for future analysis. A quick collect handheld device is ideal for service, reliability, operations, or maintenance personnel as part of a walk around data collection program.

When a machine is easily accessible, simply apply the head of the device to it and connect either to a device application or to an external application and look at the live stream vibrations and temperature measurements.

When a machine is not easily accessible but has already a vibration sensor fixed on it with a cable, it is possible to go to the machine with the device, to connect the external sensor to the device, and connect either to a device application or to an external application and look at the live stream vibrations measurements.

It is further possible to perform a maintenance route. Some machines are easily accessible and some less. Measurements points have been defined in a specific application. In this case it is possible to go machine to machine, using the specific application and using the device to perform vibrations and temperatures measurements, or to connect to an external vibration sensor already in place on a machine and get vibrations measurements. Later, measurements could be checked.

With regard more specifically to vibrations, some sensors use the principle of mechanical inertia. A mass can move relative to a reference point, against the action of elastic means. The movements of the mass cause variations in electrical values, which are used to evaluate the vibrations. Inertial sensors are useful, but they have some disadvantages, such as a certain bulk or a variation in efficiency over time due to wear.

Other sensors use the piezoelectric principle for monitoring and maintenance, capturing mechanical vibrations that are transmitted through a material. Piezo sensors work in analogy mode, so they perceive differences between strong shocks and weak blows. Piezo sensors convert the vibrations to be measured into an electrical quantity and process the latter in such a way that the electrical signals can be easily transmitted and processed downstream. Piezo sensors are useful, but they also have specificities in their applications.

For example, these sensors are sensitive mainly to high frequencies. These sensors are very suitable for measuring frequencies in high or relatively high temperature environments. The material in these sensors is sensitive in only one direction. Even if it is small, a piezoelectric sensor has a certain volume which sometimes makes it difficult to implement.

Whatever the type of sensor used, it is advantageous to reduce the weight and bulk of the device. Nevertheless, it appeared that in certain cases this reduces reliability. For example, damage has sometimes been observed at the level of an electrical connection of a sensor to an electronic control card of a device.

### SUMMARY

The present disclosure wishes, among other things, to overcome these drawbacks. In particular, the present disclosure wishes to reduce the size of a device while maintaining good reliability. The present disclosure also wishes to improve the measurement of vibrations in low frequency registers; it is a question of widening the vibration measurement ranges. The present disclosure also wishes measuring frequencies in low or relatively low temperature environments, mainly between −40° C. and +125° C. Another objective of the present disclosure is to allow vibration measurements in different directions with the same sensor. The present disclosure further seeks to reduce the dimensions of a vibration sensor, to allow to reduce the dimensions of a measuring head. Additional objectives of the present disclosure are controlling the noise level linked to the information provided by a sensor, allowing customization of a sensor or of a head equipped with a sensor, reducing the costs of manufacturing, and implementing a sensor or a head equipped with a sensor.

The present disclosure relates to a handheld measuring apparatus comprising a measuring head, a control device, and a power supply device.

The measuring head comprises a micro-electromechanical system for capturing vibrations, the micro-electromechanical system being attached to a body of the measuring head by a mechanical connection and being electrically connected to the control device.

The micro-electromechanical system is directly secured onto a circuit board itself attached to the body of the measuring head.

The measuring head comprises a sensor and a flexible path extending between the sensor and the circuit board.

The body of the measuring head is provided with a first surface for receiving the circuit board and with a second surface for guiding the flexible path.

A recess is provided on the second surface. A portion of the flexible path is guided into the recess.

The micro-electromechanical system, called MEMS, makes it possible to measure low frequency, medium frequency, or high frequency vibrations. The measurement range can be chosen. Also, MEMS allow vibrations to be measured when temperatures are low or moderate. Further, vibrations can be measured in different directions. And because MEMS are very small, the dimensions of the measuring head can be reduced.

For example, the MEMS is soldered directly onto the circuit board. Attachment of the last to the measuring head can be done by any known means. In a non-limiting manner, a mechanical connection is easy and inexpensive to make. A flexible path allows to make an electrical connection that resists vibrations and adapts to thermal expansion. The measuring head allows measurements of different types.

The recess increases the reception volume of the flexible path. Thanks to the recess, deformation of the flexible path occurs in pure bending, without twisting. The recess allows control of the radius of curvature of the flexible path. This reduces mechanical stress in said path. Among the resulting advantages, there is a reduced size of the head, and greater reliability of the device.

The recess may be curved. This promotes bending of the flexible path.

Thanks to the recess, the folded length of the flexible path is greater. Said flexible path can be bent with a large radius of curvature compared to its thickness. The flexible path is curved in its thickness direction only.

Preferably, the recess comprises a first concave portion on the side of the first surface, and a second planar portion extending the first concave portion on the side opposite to the first surface.

The first surface and the second surface of the body of the measuring head may be perpendicular. This facilitates the construction of the body.

The measuring head may further comprise an additional flexible path extending between the circuit board and the control device. The sensor, the flexible path, the circuit board and the additional flexible path may follow each other in the order listed.

The sensors are thus electrically connected to the control device in a simple and reliable way.

The circuit board may be screwed to the body of the head.

A screw connection is simple, reversible, and economical. It facilitates maintenance because it allows replacement of the circuit.

The circuit board may have the general shape of a plate.

This shape is interesting because it allows easy cutting to the desired dimensions, and rapid welding of components by dipping.

Preferably, the circuit board is perpendicular to an external contact surface of the head.

This makes it easier to set up the circuit in the head.

The sensor may be intended to measure temperatures.

This allows the device, already measuring frequencies, to control the most useful values for the maintenance of a machine.

The control device may be an electronic device.

This reduces the energy consumption of the device and gives it a minimalist footprint.

### BRIEF DESCRIPTION OF THE DRAWINGS

The present disclosure and its advantages will be better understood by studying the detailed description of specific embodiment given by way of a non-limiting example and illustrated by the appended drawings on which:

FIG. 1 is a global view of a handheld measuring apparatus, according to an example of the present disclosure;

FIG. 2 is an exploded perspective view of the apparatus according to FIG. 1;

FIG. 3 is a perspective view of a body of a measuring head of the apparatus of FIGS. 1 and 2;

FIG. 4 is a perspective view of components for the measuring head of FIG. 3;

FIG. 5 is a perspective view of the components of FIG. 4 placed in the body of FIG. 3;

FIG. 6 is an exploded perspective view of the components of FIG. 4 for the body of FIG. 3;

FIG. 7 is a perspective view of components for the measuring head of FIG. 3, according to a variant embodiment of the example; and

FIG. 8 is a perspective view of the components of FIG. 7 placed in the body of FIG. 3.

### DETAILED DESCRIPTION

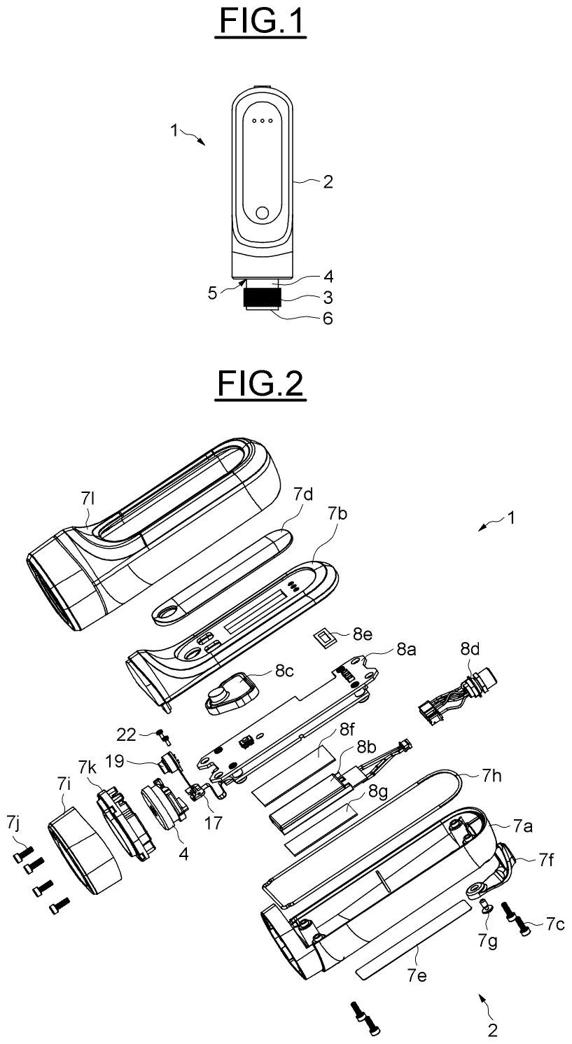

A handheld measuring apparatus 1, as illustrated in FIG. 1, includes a housing 2 whose general shape is that of a handle. A measuring head 3 is attached to one end of the housing 2, said head 3 comprising a body 4 extending in length between an attaching end 5 to the housing 2 and a free end 6, which is an external contact surface of the head 3. The body 4 is made from any suitable material, such as a metal, a metal alloy, or a composite material.

As shown in FIG. 2, the housing 2 comprises a hollow main body 7a and a closing lid 7b. Screws 7c allow the lid 7b to be held on the body 7a to close the housing 2. An exterior panel 7d covers part of the lid 7b, a label sticker 7e is affixed to the hollow main body 7a, and a protective tip 7f, made for example of rubber, is maintained at a free end of the housing 2, for example by means of a screw 7g. In a non-limiting manner, the measuring apparatus 1 also includes a seal 7h between the hollow main body 7a and the lid 7b of 2. The apparatus 1 further includes a cap 7i affixed to the housing 2, for example by means of screws 7j, for supporting measuring head 4. A damper 7k, made from any suitable material such as rubber, is placed between the cap 7i and the measuring head 4. Non-obligatory, a protection 7l, made for example of rubber, can be put in place on the housing 2. Said protection 7l allows access to the exterior panel 7d.

The measuring apparatus 1 includes an electronic control device 8a and a power supply device such as a battery 8b. The apparatus is controlled for example by a button 8c. An external connector 8d allows for example battery recharging, data transmission, or other. A seal 8e is put in place between the electronic control device 8a and the lid 7b, a seal 8f is put in place between the battery 8b and the electronic control device 8a, and a seal 8g is put in place between the battery 8b and the main body 7a.

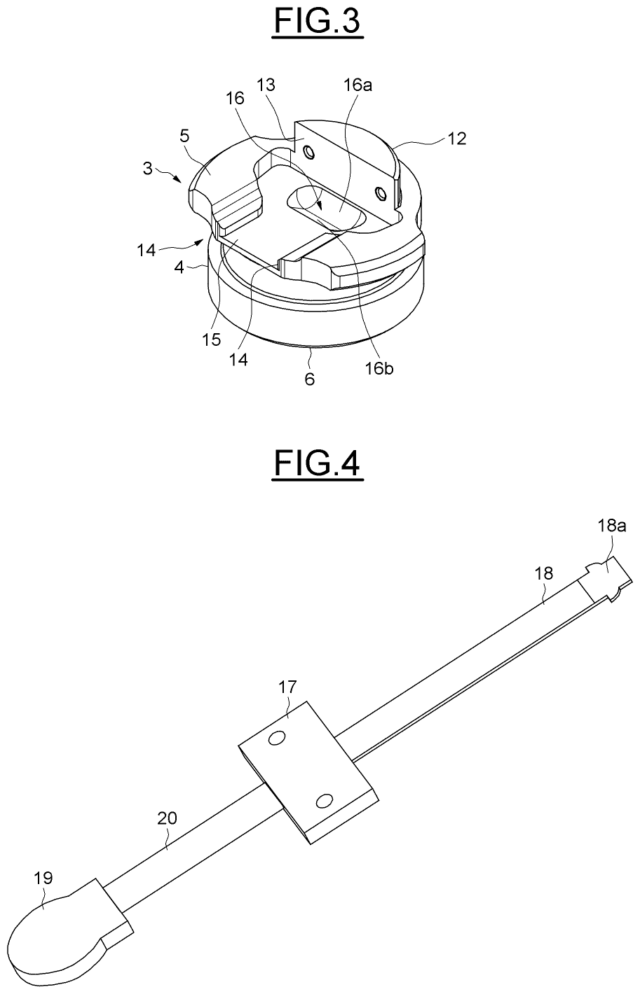

As explained by means of FIGS. 3 to 6, the measuring head 3 comprises a micro-electromechanical system 11 for capturing vibrations, the micro-electromechanical system 11 being attached to the body 4 of the measuring head 3 by a mechanical connection and being electrically connected to the control device 8a.

The micro-electromechanical system 11, called MEMS, makes it possible to measure low frequency, medium frequency, or high frequency vibrations. The measurement range can be chosen. The MEMS is a miniaturized sensor which occupies a limited volume and acts on real-time information about its physical environment.

In the example described the handheld measuring apparatus 1 includes one MEMS, but it could include several MEMS.

For example with regard to FIG. 3 in a non-limiting manner, the body 4 of the measuring head 3, extending between the attaching end 5 and the free end 6, has the general shape of a cylinder. The measuring head 3 includes a finger 12 projecting from the body 4, the finger 12 having a flat face 13 perpendicular to the attaching end 5 and to the free end 6. The body 4 has a notch 14 on the side of the attaching end 5, a bottom 15 of the notch 14 being parallel to the attaching end 5, and perpendicular to the flat face 13 of the finger 12. A recess 16 is provided on the bottom 15 of the notch 14. The recess 16 comprises a first concave portion 16a extending from the bottom 15 and located on the side of the first surface 13, and a second planar portion 16b extending the first concave portion 16a on the side opposite to the first surface 13 and connected to the bottom 15.

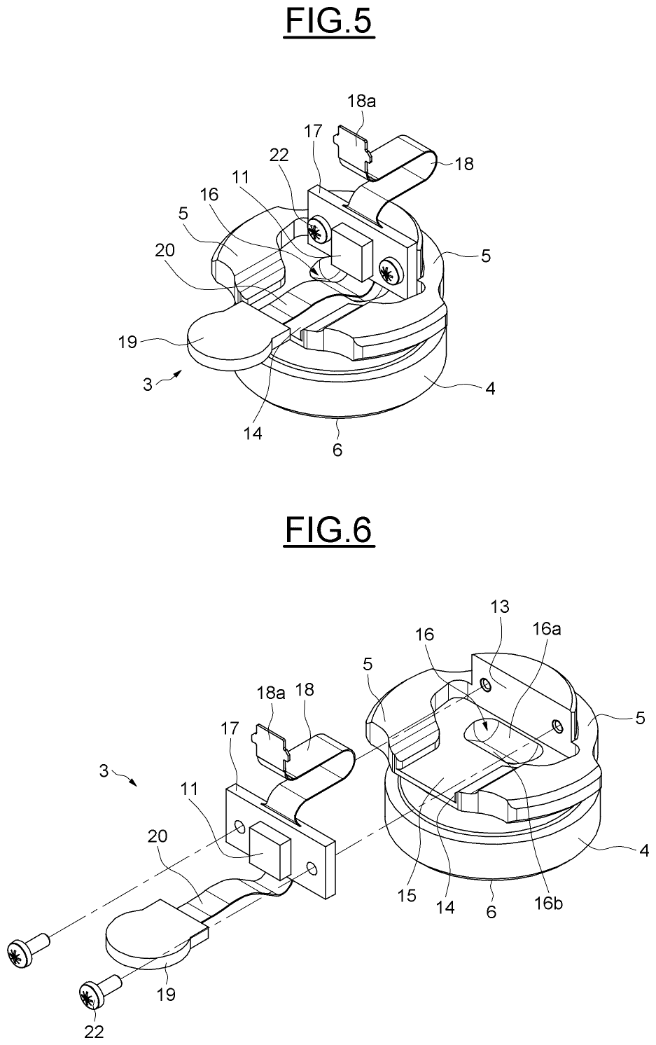

As shown on FIG. 4, the measuring head further comprises a circuit board 17, a first flexible path 18, a temperature sensor 19, and a second flexible path 20. The first flexible path 18 is provided at its free end with a connector 18a. The first flexible path 18 electrically connects the circuit board 17 to the control device 8a. The second flexible path 20 electrically connects the sensor 19 to the circuit board 17. The temperature sensor 19, the second flexible path 20, the circuit board 17 and the first flexible path 18 follow each other in the order listed and can be placed on the body 4 as shown in FIG. 5 and FIG. 6.

The first flexible path 18 is folded, which allows it to adapt to thermal expansions. The circuit board 17 is reversibly secured to the body 4 of the head 3, by a means represented in the form of screws 22. More generally, the circuit board 17 is secured to a first surface of the body 4, which in the example is the flat surface 13 of the finger 12. The MEMS is secured onto the circuit board 17 in a non-limiting way by soldering. The second flexible path 20 is guided towards the circuit board 17 inside the notch 14.

The body 4 of the measuring head 3 has a second surface for guiding the second flexible path 20, which in the example is the bottom 15 of the notch 14. The second flexible path 20 is guided by the recess 16. The second flexible path 20 follows the recess 16. The second flexible path 20 is curved in its thickness direction only. The second flexible path 20 comes into contact with the concave portion 16a and the planar portion 16b of the recess.

The recess 16, provided on the second surface 15, allows flexion of the second flexible path 20 along a large radius of curvature, in comparison with the thickness of the path 20. This prevents the appearance of cracks in the flexible path 20 and improves the reliability of the measuring head 3. The length of the recess 16 may be equal to or greater than the width of the notch 14.

In addition, the shape of the circuit board 17 is that of a parallelepiped. This shape can serve as a means of visual recognition in correlation with one or more properties of the MEMS.

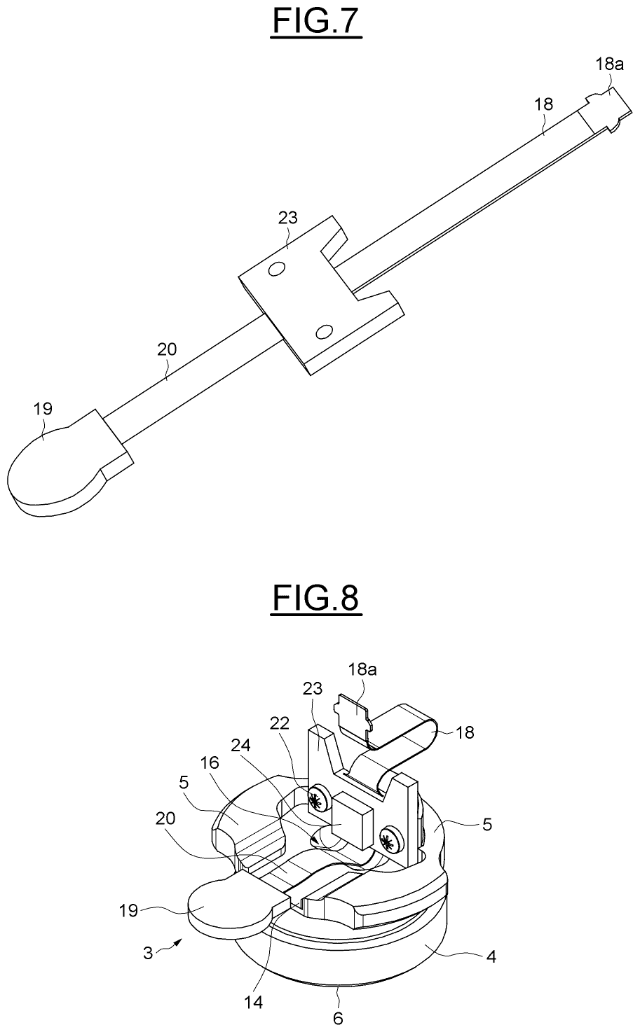

An alternative embodiment for the same example of the present disclosure is shown in FIGS. 7 and 8.

The measuring head 3 still comprises a body 4, a first flexible path 18, a temperature sensor 19, and a second flexible path 20. The head 3 also has a circuit board 23 and a MEMS 24. Here the shape of the circuit board 23 is that of a parallelepiped one edge of which has a notch. The MEMS 24 may be different from the previous one 11.

What is claimed is:

1. A handheld measuring apparatus comprising:
a power supply device;
a control device; and
a measuring head comprising a body, a circuit board attached to the body, and a micro-electromechanical system for capturing vibrations, the micro-electromechanical system being attached to the body by a mechanical connection and being electrically connected to the control device, the micro-electromechanical system being directly secured onto the circuit board, the measuring head comprising a sensor and a flexible path extending between the sensor and the circuit board, the body including a first surface and a second surface, the circuit board being received by the first surface, the second surface guiding the flexible path, the body including a recess in the second surface, a portion of the flexible path being guided into the recess.

2. The apparatus according to claim 1, wherein the recess comprises a first concave portion on the side of the first surface, and a second planar portion extending the first concave portion on the side opposite to the first surface.

3. The apparatus according to claim 1, wherein the first surface and the second surface are perpendicular.

4. The apparatus according to claim 1, wherein the measuring head further comprises an additional flexible path extending between the circuit board and the control device.

5. The apparatus according to claim 4, wherein the sensor, the flexible path, the circuit board, and the additional flexible path follow each other in the order listed.

6. The apparatus according to claim 1, wherein the circuit board is screwed to the body of the head.

7. The apparatus according to claim 1, wherein the circuit board has the general shape of a plate.

8. The apparatus according to claim 1, wherein the circuit board is perpendicular to an external contact surface of the head.

9. The apparatus according to claim 1, wherein the sensor is intended to measure temperatures.

10. The apparatus according to claim 1, wherein the control device is an electronic device.

11. The apparatus according to claim 2, wherein the first surface and the second surface are perpendicular.

12. The apparatus according to claim 11, wherein the measuring head further comprises an additional flexible path extending between the circuit board and the control device.

13. The apparatus according to claim 12, wherein the sensor, the flexible path, the circuit board, and the additional flexible path follow each other in the order listed.

14. The apparatus according to claim 13, wherein the circuit board is screwed to the body of the head.

15. The apparatus according to claim 14, wherein the circuit board has the general shape of a plate.

16. The apparatus according to claim 15, wherein the circuit board is perpendicular to an external contact surface of the head.

17. The apparatus according to claim 16, wherein the sensor is intended to measure temperatures.

18. The apparatus according to claim 17, wherein the control device is an electronic device.
